(19) United States
(12) Patent Application Publication
(10) Pub. No.: US 2019/0379200 A1
(43) Pub. Date: Dec. 12, 2019

(54) AIR PULSER FOR A MOTOR VEHICLE POWERED BY TWO VOLTAGES

(71) Applicant: Valeo Systemes Thermiques, Le Mesnil Saint Denis (FR)

(72) Inventors: Jonathan Fournier, Le Mesnil Saint-Denis (FR); Mickael Bigey, Le Mesnil Saint Denis Cedex (FR); William Lapierre, Le Mesnil Saint Denis Cedex (FR)

(73) Assignee: Valeo Systemes Thermiques, Le Mesnil Saint Denis (FR)

(21) Appl. No.: 16/335,401

(22) PCT Filed: Aug. 25, 2017
(86) PCT No.: PCT/FR2017/052279

§ 371 Date: Aug. 19, 2019

(30) Foreign Application Priority Data
Sep. 23, 2016 (FR) 1658989

(51) Int. Cl. H02H 3/20; G01R 19/165; B60R 16/03; H02J 1/14

(52) U.S. Cl. CPC H02H 3/20; G01R 19/16523; H02J 1/14; B60R 16/03; G01R 19/16542

(57) ABSTRACT

The invention relates to an air pulser (1) for a motor vehicle, designed to be powered by a first voltage (U1) and a second voltage (U2), according to which the air pulser (1) comprises: a first interface (I48) for connecting to a power supply network (G48) supplying the second voltage (U2); a second interface (ILW) for connecting to a communication bus (BLW); a functional module (11) connected to the first connection interface (I48); a main switch (Q2) connected to the functional module (11), designed to enable signals (DAT) to travel through the communication bus (BLW); and a first protection module (10) for isolating the communication bus (BLW) from the power supply network (G48) when there is an overvoltage (USS) between the functional module (11) and the second connection interface (ILW).

### TECHNICAL FIELD OF THE INVENTION

The present invention relates to an air pulser for a motor vehicle designed to be powered by a first voltage and by a second voltage.

It is particularly, but not exclusively, applicable in motor vehicles.

### TECHNOLOGICAL BACKGROUND OF THE INVENTION

In the field of air pulsers for motor vehicles, it is known practice to power an air pulser by two voltages, one being a high voltage designed for driving loads of the air pulser and the other being a lower voltage designed for elements controlling the current in the driving loads. The driving loads and the controlling elements form part of one and the same functional module. To this end, the air pulser comprises a communication bus over which air flow rate setpoints can be sent to it and a connection interface with an electrical power supply network, called high-power electrical power supply network, which supplies the high voltage. The communication bus is powered by the same power supply network as the controlling elements.

One drawback with this state of the art is that if a problem, such as a short circuit in a nonlimiting example, occurs in the functional module comprising said controlling elements, there is a risk of the high voltage supplied by the high-power electrical power supply network being provided on the communication bus, thus creating a hazardous voltage, called overvoltage, which risks damaging it.

In this context, the present invention aims to resolve the drawback mentioned above.

### DETAILED DESCRIPTION OF THE INVENTION

To this end, the invention proposes an air pulser for a motor vehicle designed to be powered by a first voltage and by a second voltage, wherein the air pulser comprises:
a first connection interface with an electrical power supply network designed to supply the second voltage;
a second connection interface with a communication bus;
a functional module linked to the first connection interface;
a main switch linked to the functional module designed to convey signals over the communication bus;
a first protection module designed to isolate the communication bus from the electrical power supply network when there is an overvoltage between the functional module and the second connection interface.

Thus, as will be seen in detail hereinbelow, the first protection module will detect an overvoltage between the functional module and the second connection interface, and will deactivate the main switch so that it is opened following the detection of such an overvoltage. This will cause the electrical power supply network to be disconnected from the communication bus. The latter will therefore not be impacted by said overvoltage and will consequently be protected.

According to nonlimiting embodiments, the air pulser can further comprise one or more additional features out of the following:

According to a nonlimiting embodiment, the first protection module comprises:
an overvoltage detection module comprising:
   a protection diode;
   a first protection switch designed to close when the protection diode is switched on;
a secondary switch designed to open when there is said overvoltage so as to open the main switch;
a second protection switch designed to open when the first protection switch closes so as to open the secondary switch.

The opening of the secondary switch avoids having currents which circulate from the electrical power supply network to the communication bus. That thus makes it possible to protect the communication bus against an overvoltage.

According to a nonlimiting embodiment, the signals are low logic signals.

According to a nonlimiting embodiment, the low logic signals are 0 volt signals.

According to a nonlimiting embodiment, said overvoltage is generated by a short circuit in the electrical power supply network.

According to a nonlimiting embodiment, the air pulser further comprises a protection diode designed to protect the communication bus if the first voltage is above a threshold voltage of said protection diode. That makes it possible to protect said communication bus.

According to a nonlimiting embodiment, the air pulser further comprises a secondary blocking diode designed to prevent a current from circulating in the second protection switch. That protects said second protection switch.

According to a nonlimiting embodiment, the air pulser further comprises a main pulling resistor designed to guarantee the opening of the main switch when there is said overvoltage.

According to a nonlimiting embodiment, the air pulser further comprises a secondary pulling resistor designed to guarantee the opening of the secondary switch when there is said overvoltage.

According to a nonlimiting embodiment, the air pulser further comprises a base resistor designed to guarantee the closure of the secondary switch when a current circulates in said secondary switch.

According to a nonlimiting embodiment, the air pulser further comprises a resettable fuse designed to protect the communication bus against an overcurrent. That makes it possible to protect said communication bus.

According to a nonlimiting embodiment, the air pulser further comprises a tertiary blocking diode designed to guarantee that the main switch remains open.

According to a nonlimiting embodiment, the air pulser further comprises a protection diode designed to protect the main switch against an increase in said first voltage. That prevents it from being damaged.

According to a nonlimiting embodiment, the first voltage is lower than the second voltage.

According to a nonlimiting embodiment, the first voltage is substantially equal to 12 volts.

According to a nonlimiting embodiment, the second voltage is substantially equal to 48 volts.

According to a nonlimiting embodiment, the first voltage is generated from the second voltage. It is therefore fixed and does not undergo variations originating from a battery voltage for example.

According to a nonlimiting embodiment, the air pulser comprises a voltage regulator designed to generate the first voltage from the second voltage.

According to a nonlimiting embodiment, the communication bus is an LIN bus or a PWM bus. An LIN bus makes it possible to use only a single wire to send and receive signals. Thus, only a single wire is used for two different functions, namely a diagnostic function and a setpoint function. It is also possible to use any other type of communication bus that makes it possible to have a bidirectional communication. A PWM bus makes it possible to receive or send signals with a controlled duty cycle.

According to a nonlimiting embodiment, the functional module comprises an electronic driver module designed to be powered by the first voltage and to receive and/or transmit signals via the communication bus. The functional module can thus exchange information with another electronic device via its electronic driver module. It can thus send diagnostic information and receive setpoint information.

According to a nonlimiting embodiment, the functional module comprises at least one driving load powered by the second voltage and at least one associated controlling element powered by the first voltage, said controlling element being designed to control said at least one driving load. In particular, said controlling element is designed to control the current of said driving load.

According to a nonlimiting embodiment, the first connection interface is linked to a common ground, and the air pulser further comprises a second protection module designed to isolate the communication bus from the electrical power supply network upon a loss of the common ground.

According to a nonlimiting embodiment, the second protection module the second protection module comprises:
said secondary switch;
said second protection switch;
said secondary blocking diode.

Thus, some of the components of the first protection module are used to protect the communication bus against a loss of common ground. The costs and the complexity of the architecture of the air pulser 1 for the protections are thus reduced.

The invention applies also to an electrical heating device for a motor vehicle. Thus, according to a nonlimiting embodiment, an electrical heating device for a motor vehicle is also proposed that is designed to be powered by a first voltage and by a second voltage, wherein the electrical heating device comprises:
a first connection interface with an electrical power supply network designed to supply the second voltage;
a second connection interface with a communication bus;
a functional module linked to the first connection interface;
a main switch linked to the functional module designed to convey signals over the communication bus;
a first protection module designed to isolate the communication bus from the electrical power supply network when there is an overvoltage between the functional module and the second connection interface.

### BRIEF DESCRIPTION OF THE FIGURES

The invention and its various applications will be better understood on reading the following description and on studying the accompanying figures:

FIG. 1 represents a diagram according to a nonlimiting embodiment of the invention of an air pulser for a motor vehicle, said air pulser being powered by a first voltage and by a second voltage and linked to a communication bus and comprising a first overvoltage protection module and a second module protecting against a loss of ground;

FIG. 2a represents a diagram of the air pulser of FIG. 1 with the detail of the electronic components of the first protection module according to a nonlimiting embodiment;

FIG. 2b represents a diagram of the air pulser of FIG. 1 with the detail of the electronic components of the second protection module according to a nonlimiting embodiment;

FIG. 3 represents a diagram of the air pulser of FIG. 1 when there is a short circuit in the electrical power supply network according to a nonlimiting embodiment;

FIG. 4 represents a diagram of the air pulser of FIG. 1 when the ground is lost according to a nonlimiting embodiment;

FIG. 5 represents a diagram of the air pulser of FIG. 1 when it receives signals from another electronic device, according to a nonlimiting embodiment;

FIG. 6 represents a diagram of the air pulser of FIG. 1 when it sends signals to another electronic device, according to a nonlimiting embodiment.

### DESCRIPTION OF EMBODIMENTS OF THE INVENTION

The identical elements, by structure or by function, that appear in the different figures retain the same references, unless specified otherwise.

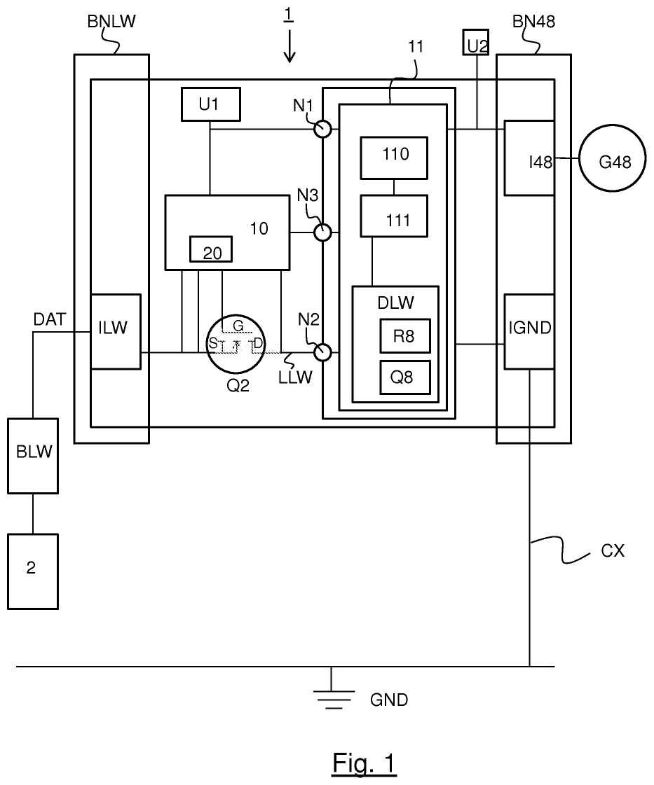

The air pulser 1 for a motor vehicle is described with reference to FIGS. 1 to 6 according to a nonlimiting embodiment.

A motor vehicle should be understood to mean any kind of motorized vehicle.

In a nonlimiting embodiment, an air pulser 1 is used in an air conditioning, ventilation and/or heating device (not illustrated), called HVAC, for “Heating Ventilation and Air Conditioning”, for a motor vehicle or for cooling the engine (not illustrated) of the motor vehicle.

The air pulser 1 is powered by a first voltage U1 and by a second voltage U2. The first voltage U1 is generated from the second voltage U2. An electrical power supply network G48 is designed to supply the second voltage U2. Hereinafter in the description, the terms electrical power supply network and network will be used without differentiation.

As illustrated in FIG. 1, the air pulser 1 comprises:
a first connection interface I48 with the electrical power supply network G48;
a second connection interface ILW with a communication bus BLW;
a functional module 11 linked to the first connection interface I48;
a main switch Q2 linked to the functional module 11 and designed to convey signals DAT over the communication bus BLW;
a first protection module 10 designed to isolate the communication bus BLW from the electrical power supply network G48 where there is an overvoltage USS between the functional module 11 and the second connection interface ILW.

The air pulser 1 forms part of a communication network NLW.

In a nonlimiting example, an overvoltage USS appears between the functional module 11 and the second connection interface ILW, when there is a short circuit CC in the functional module 11.

Such a short circuit CC is taken as a nonlimiting example hereinafter in the description. Hereinafter in the description, a short circuit CC in the functional module 11 will also be cited simply as short circuit CC. It will be noted that when a short circuit CC occurs in the functional module 11, that means that the elements of the functional module 11, including the electronic driver module DLW, will be either defective or destroyed.

As will be seen in detail hereinbelow, upon a short circuit CC on the functional module 11 which generates such an overvoltage USS, all of the components of the functional module 11 rise to the potential of the second voltage U2 supplied by the electrical power supply network G48. That leads to the appearance of potential differences and consequently of currents which circulate between said functional module 11 and:
the first protection module 10;
the communication bus BLW.

These currents and voltages risk damaging the communication bus BLW in particular. The first protection module 10 makes it possible to protect the communication bus BLW against said currents and voltages.

In particular, the first protection module 10 will make it possible to isolate the second connection interface ILW and consequently the communication bus BLW from a hazardous voltage, namely from said overvoltage USS. In effect, this second connection interface ILW which is rated for a low voltage (here 12 V) cannot withstand an excessively high voltage, for example higher than 40 V.

The first protection module 10 comprises:
a overvoltage detection module 100 comprising:
   a protection diode D1,
   a first protection switch Q1,
a secondary switch Q6;
a second protection switch Q4.

As described in detail hereinbelow, when there is a short circuit CC which leads to an overvoltage USS, the first protection switch Q1 will close which will lead to the opening of the second protection switch Q4. The opening of the second protection switch Q4 will lead to the opening of the secondary switch Q6. Finally, the opening of the secondary switch Q6 will lead to the opening of the main switch Q2. The opening of the main switch Q2 will make it possible to isolate the second connection interface ILW from the network G48 and consequently isolate the communication bus BLW from the network G48. The communication bus BLW is thus protected from said overvoltage USS.

In a nonlimiting embodiment, the air pulser 1 further comprises a protection diode D7.

In a nonlimiting embodiment, the air pulser 1 further comprises a main pulling resistor R7.

In a nonlimiting embodiment, the air pulser 1 further comprises a secondary pulling resistor R15.

In a nonlimiting embodiment, the air pulser 1 further comprises a secondary blocking diode D11.

In a nonlimiting embodiment, the air pulser 1 further comprises a base resistor R14.

The various elements of the air pulser 1 are described in more detail hereinbelow.

Connection Interfaces I48, ILW, IGND

The first connection interface I48 is designed to connect the air pulser 1 with the electrical power supply network G48. It is an input which makes it possible to receive a voltage supplied by the electrical power supply network G48.

The network G48 is linked to a battery (not illustrated) of the motor vehicle which is a voltage generator.

In a nonlimiting embodiment, the first voltage U1 is lower than the second voltage U2.

In a nonlimiting embodiment, the first voltage U1 is substantially equal to 12 V (volts). This is a low-power voltage.

In a nonlimiting embodiment, the second voltage U2 is substantially equal to 48 V (volts). This is a high-power voltage. The network G48 is also called high-power network.

It will be noted that a battery, linked to the network G48, which normally supplies a voltage of 48 V, makes it possible to supply a voltage which can rise to 58 V.

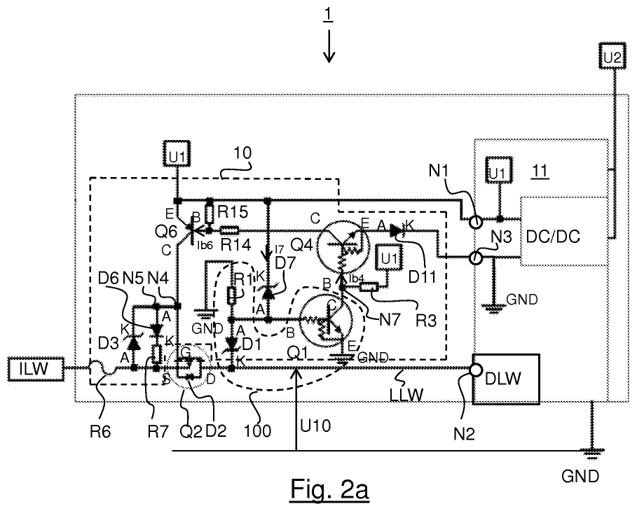

In a nonlimiting embodiment, the first voltage U1 is generated from the second voltage U2. To this end, in a nonlimiting embodiment, the air pulser 1 further comprises a voltage regulator. More particularly, the functional module 11 comprises said voltage regulator. In nonlimiting variants, the voltage regulator is a DC/DC converter (illustrated in FIGS. 2a and 2b) or a linear regulator, designed to perform the conversion from 48 V to 12 V.

Since a DC/DC converter or a linear regulator is known to the person skilled in the art, they are not described here. The DC/DC converter or the linear regulator thus make it possible to supply a first voltage U1 which is fixed, namely which does not undergo variations due to variations of a battery voltage, since said first voltage U1 is generated internally.

Hereinafter in the description, the expressions first voltage U1 or voltage U1, and second voltage U2 or voltage U2 will be used without differentiation.

Hereinafter in the description, the voltages of 12 V for the voltage U1 and of 48 V for the voltage U2 will be taken as nonlimiting examples.

In a nonlimiting embodiment, the first connection interface I48 is linked to a ground GND, also called common ground GND.

It is linked by a ground cable CX (illustrated in FIG. 1 for example) to said common ground GND.

The second connection interface ILW is designed to connect the air pulser 1 with a communication bus BLW. It is an input.

The connection interfaces I48, ILW thus comprise electrical connections designed to make the connections respectively with the electrical power supply network G48 and the communication bus BLW.

In a first nonlimiting embodiment, the communication bus BLW is an LIN (Local Internetconnect Network) communication bus. The air pulser 1 thus forms part of a so called LIN communication network NLW. An LIN communication bus is a bidirectional communication bus. Thus, an LIN communication network makes it possible to use only a single wire to communicate signals.

In a second nonlimiting embodiment, the communication bus BLW is a PWM (“Pulse Modulation Width”) communication bus. The air pulser 1 thus forms part of a so-called PWM communication network NLW. A PWM communication bus is a unidirectional bus. Thus, in this case, the air pulser 1 comprises two unidirectional PWM communication buses, one being used to receive signals, and the other being used to send signals.

The communication bus BLW makes it possible to convey signals DAT from the air pulser 1 to an external electronic device 2 (described later) and/or from the external electronic device 2 to the air pulser 1. It will be noted that there is a communication line LLW internal to the air pulser 1 (illustrated in FIG. 1 for example) between the functional module 11 and the second connection interface ILW over which said signals from the functional module 11 pass. In a nonlimiting embodiment, this communication line is an electronic track.

As illustrated in FIG. 1 also, in a nonlimiting embodiment, the air pulser 1 further comprises a ground interface IGND. The ground interface IGND is an output. It will be noted that, in a nonlimiting example, the ground cable CX links the ground interface IGND to the chassis of the motor vehicle which forms a ground plane.

In a nonlimiting embodiment, the first protection module 10, the functional module 11 and the main switch Q2 form part of one and the same printed circuit board, also called PCBA (“Printed Circuit Board Assembly”). This printed circuit board PCBA is thus linked to the ground plane formed by the chassis of the motor vehicle.

As illustrated in FIG. 1, in a nonlimiting embodiment, the second connection interface ILW forms part of a connector BNLW.

As illustrated in FIG. 1, in a nonlimiting embodiment, the first connection interface I48 and the ground interface IGND form part of one and the same connector BN48. That makes it possible to limit the number of connectors.

Main Switch Q2

The main switch Q2 is designed to convey signals DAT over the communication bus BLW.

To this end, it is connected to the communication bus BLW via the second connection interface ILW. It is arranged between the communication bus BLW and the functional module 11, in particular its electronic driver module DLW (described later).

In a nonlimiting embodiment, the main switch Q2 is a MOSFET transistor. In a nonlimiting variant embodiment, it is an N-channel transistor. In this case, the gate G of the transistor receives the first voltage U1, namely the voltage of 12 V in the nonlimiting example taken, the source S is connected to the communication bus BLW via the second connection interface ILW, and the drain D is connected to the electronic driver module DLW.

The main switch Q2 comprises a threshold voltage Vgsth.

The main switch Q2 is closed when the voltage Vgs thereof is equal to the voltage U1 supplied by the first network G12, namely, here, 12 V. When the signals DAT which circulate over the communication bus BLW are at 0 V in a nonlimiting embodiment, the drain D and the source S are at the 0 V potential. Since the gate G is powered by the voltage U1 of 12 V, the voltage Vgs is therefore at least 12V. Since Vgs is higher than a threshold voltage Vgsth, the main switch Q2 closes correctly. In a nonlimiting example, Vgsth=2V.

In a nonlimiting embodiment, the main switch Q2 comprises a breakdown voltage above 48 volts. In a nonlimiting variant embodiment, the breakdown voltage is substantially equal to 100 volts. The main switch Q2 thus supports the voltage U2, here 48 V, that it receives (in particular between the source S and the drain D in the nonlimiting embodiment of MOSFETS) upon an overvoltage USS or when the common ground GND is lost.

The main switch Q2 is open when the voltage Vgs is lower than the voltage Vgsth, i.e. when Vgs is substantially equal to 0 V in a nonlimiting example. As will be seen hereinbelow, the main switch Q2 opens:
by virtue of the first protection module 10 when there is an overvoltage USS; and
by virtue of the second protection module 20 when the common ground GND is lost.

Thus, as will be seen later in the description, the first protection module 10 makes it possible to protect the communication bus BLW against an overvoltage USS, whereas the second protection module 20 makes it possible to protect the communication bus BLW against a loss of common ground GND.

Protection Diode D3

In a nonlimiting embodiment, the air pulser 1 further comprises a protection diode D3 associated with the main switch Q2, illustrated in FIG. 2a or 2b. It is arranged in parallel with the main pulling resistor R7 (described later) and the tertiary blocking diode D6 (described later). Its anode A is linked to the source S of the main switch Q2 and its cathode K is linked to the gate of the main switch Q2.

This protection diode D3 is designed to protect the main switch Q2 against an increase in the first voltage U1, in particular against an excessively high voltage between its gate G and its source S.

In effect, if a fault occurs on the node N1, the first voltage U1 that it supplies can greatly increase and be on top of the gate-source voltage V_{GS} of the main switch Q2 so as to damage it. In a nonlimiting example, a fault can occur in the case of a fault on the alternator or the starter of the motor vehicle.

In a nonlimiting embodiment, the protection diode D3 is a zener diode. The zener diode D3 comprises a threshold voltage VS3. If the voltage V_{GS} of the main switch Q2 becomes greater than or equal to this voltage VS3, the zener diode clips said voltage V_{GS} so that it is equal to the threshold voltage VS3. Thus, in a nonlimiting example, the threshold voltage VS3 is equal to 20 V. The main switch Q2 is thus protected.

Resettable Fuse R6

In a nonlimiting embodiment, the air pulser 1 further comprises a resettable fuse R6 illustrated in FIG. 2a or 2b.

The resettable fuse R6 is arranged in series with the main switch Q2, in particular between said main switch Q2 and the communication bus BLW.

It is designed to protect the communication bus BLW against an overcurrent. An overcurrent is a current which is too high and that said communication bus BLW cannot withstand.

In effect, during the linear operating conditions of the main switch Q2, namely during the switching phase, the main switch Q2 behaves as a resistor. Now, when there is a short circuit CC which generates an overvoltage USS, there is a potential difference between the drain D (V_{D}=48 V) and the source S (V_{S}=0 V when the signals DAT are transmitted) which generates a current (not illustrated) of the order of a few amperes. This current, called overcurrent, is dangerous because the communication bus BLW does not support this level of overcurrent. That can damage said communication bus BLW or cut the communications between the external electronic module 2 (described later) and the functional module 11 of the air pulser 1.

When an overcurrent is generated and passes through the resettable fuse R6, the latter heats up and opens, thus preventing said current from crossing the communication bus BLW.

When normal conditions are restored (there is no longer an overcurrent), the resettable fuse R6 closes.

Tertiary Blocking Diode D6

In a nonlimiting embodiment, the air pulser 1 further comprises a tertiary blocking diode D6 (illustrated in FIG. 2a or 2b) designed to guarantee that the main switch Q2 remains open.

The tertiary blocking diode D6 is arranged in series with the main pulling resistor R7. Its anode A is linked to the gate G of the main switch Q2 and its cathode K is linked to the source S of the main switch Q2 via the main pulling resistor R7.

When the main switch Q2 is open, the source voltage V_{S}=0 V or 12 V respectively if the signals DAT are transmitted or not. When V_{S}=12 V, this voltage of 12 V can be found on top of the gate voltage V_{G}, namely at the node N4 illustrated in FIG. 2a or 2b.

If the voltage V_{S} returns to 0 V (signals DAT are transmitted), the voltage of the source V_{S} is on top of the gate voltage V_{G}, but the latter does not then return to 0 V because of the stray capacitances of the main switch Q2. Thus, for a very short period it is possible to have V_{GS} higher than the threshold voltage Vgsth of the main switch Q2. For example, V_{G}=2.5 V and V_{S}=0 V. This causes the main switch Q2 to switch on. Thus, the main switch Q2 risks closing when it should remain open.

With the tertiary blocking diode D6, when it is blocked, that prevents the source voltage V_{S} from being on top of the gate voltage V_{G}. There is thus a guarantee of the main switch Q2 remaining open. Reclosing of the main switch Q2 when it is open is thus avoided.

The tertiary blocking diode D6 is blocked when the potential difference V_{AK}<VS6, with VS6 the threshold voltage of the tertiary blocking diode D6. In a nonlimiting example VS6=0.6 V.

It will be noted that the main switch Q2 opens when the secondary switch Q6 opens. When the secondary switch Q6 opens, the node N5 illustrated in FIG. 2a or 2b is at 0 V and when the voltage of the main switch Q2 V_{S}=0 V (when the signals DAT are transmitted), the voltage at the anode A of the tertiary blocking diode D6 V_{A}=0 V and the voltage at the cathode K of the diode D6 V_{K}=0 V (the cathode K being linked to the source S). This causes the tertiary blocking diode D6 to be blocked.

Functional Module

The functional module 11 is linked to the first connection interface I48 via the connector BN48 seen previously. It can thus be powered by the second voltage U2 supplied by the network G48.

In a nonlimiting embodiment, the functional module 1 comprises a voltage regulator, here a DC/DC converter, designed to convert the second voltage U2 to the first voltage U1. The functional module 11 is thus also powered by the first voltage U1.

The functional module 11 is also linked to the common ground GND via the connector BN48.

An electrical node N1, called first node, links the functional module 11 to the second connection interface ILW via the secondary switch Q6 and the main switch Q2 that are described later.

The functional module 11 comprises an electronic driver module DLW described later.

An electrical node N2, called second node, links the functional module 11, in particular its electronic driver module DLW, and the main switch Q2 via the communication line LLW.

An electrical node N3, called third node, links the functional module 11 and the first protection module 10 at the common ground GND. The third node N3 is thus linked to the common ground GND via said functional module 11.

Hereinafter in the description, an electrical node is also called node.

When a short circuit CC appears which generates an overvoltage USS, the functional module 11 rises to the potential of 48 V.

That implies an overvoltage USS at the electrical nodes N1, N2 and N3 which can rise to 48 V. It will be noted that the overvoltage USS can occur on one, two or all of these nodes N1, N2, N3.

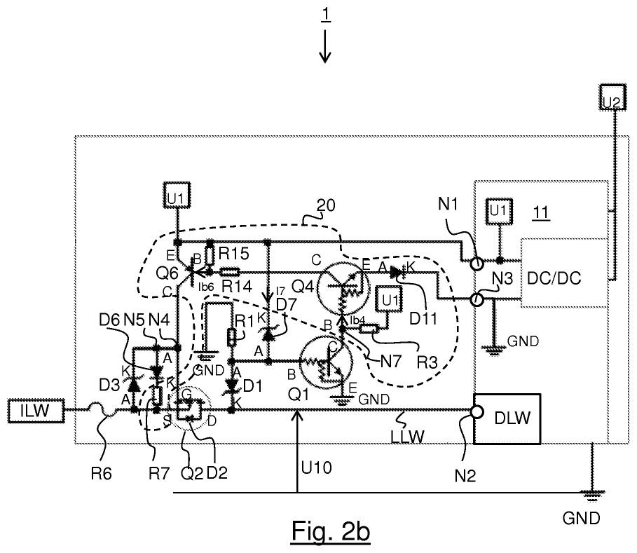

At the first node N1, a potential difference of 48 V−12 V appears (between the first node N1 and the second connection interface ILW) which leads to the appearance of the current i1 (illustrated in FIG. 3) circulating from the functional module 11 to the communication bus BLW (via the second connection interface ILW) which risks damaging it as well as the second connection interface ILW. The first protection module 10 (in particular the protection diode D7) described later prevents such a current i1 from circulating (via the secondary switch Q6) and thus protects the communication bus BLW and the second connection interface ILW. The latter are thus not damaged.

At the second node N2, on the side of the drain D of the main switch Q2 described later, a potential difference of 48 V−0 V or 48 V−12 V (between the second node N2 and the second connection interface ILW) appears which leads to the appearance of a current i2 (illustrated in FIG. 3) circulating from the electronic driver module DLW to the communication bus BLW (via the second connection interface ILW) which risks damaging it as well as the second connection interface ILW. The first protection module 10 (in particular the protection diode D1) described later and the main switch Q2 prevent such a current i2 from circulating and thus protects the communication bus BLW and the second connection interface ILW. The latter are thus not damaged.

At the third node N3, a potential difference of 48 V−0 V between this third node N3 and the communication bus BLW (all the functional module 11 having risen to the potential of 48 V) which leads to the creation of a current i3 (illustrated in FIG. 3) between said third node N3 and said communication bus BLW. The first protection module 10 (in particular the secondary blocking diode D11) described later prevents such a current i3 from circulating and thus protects the communication bus BLW and the second connection interface ILW. The latter are thus not damaged.

In a nonlimiting embodiment, the functional module 11 comprises at least one driving load 110 (illustrated in FIGS. 1 and 3) and at least one associated electronic driver element 111 (illustrated in FIGS. 1 and 3) to control the current in said at least one driving load 110.

Said driving load 110 is linked to the first connection interface I48. Thus, in the nonlimiting example taken, the electronic driver element 111 is powered by the low-power voltage U1 of 12 V and said driving load 110 is powered by the high-power voltage U2 of 48 V.

Said driving load 110 makes it possible to turn the motor of the air pulser 1. It will be noted that an air pulser 1 comprises:
an electric motor designed to be powered by the driving load 110;
a wheel of centrifugal type mounted on an axis of the electric motor;
a motor support comprising a housing in which the electric motor can be housed.

The set of these elements is configured to be mounted in an air conditioning, ventilation and/or heating device via said motor support.

In a nonlimiting embodiment, an electronic driver element 111 is mounted on the motor support of the air pulser 1. In another nonlimiting embodiment, an electronic driver element 111 is mounted at a distance from the air pulser 1 on or in the air conditioning, ventilation and/or heating device.

Since such air pulsers are known to the person skilled in the art, they are not described in detail here.

In a nonlimiting embodiment, an electronic driver element 111 comprises an electronic component such as a switch, which is, in a nonlimiting example, a MOSFET. It makes it possible to control the current which powers said driving load 110. Since the controlling of the current in the driving loads is known to the person skilled in the art, it is not described here. Conventionally, the air pulser 1 comprises a plurality of electronic driver elements. An electronic driver element 111 cooperates with an electronic driver module DLW of the functional module 11 which sends signals DAT to it. An electronic driver module DLW can control one or more electronic driver elements 111. The electronic driver module DLW is described hereinbelow.

Electronic Driver Module

As illustrated in FIGS. 1 to 6 in which the electronic driver module DLW is schematically illustrated, the electronic driver module DLW comprises a switch Q8 in series with a pull-up resistor R8. It is connected to the main switch Q2 of the air pulser 1.

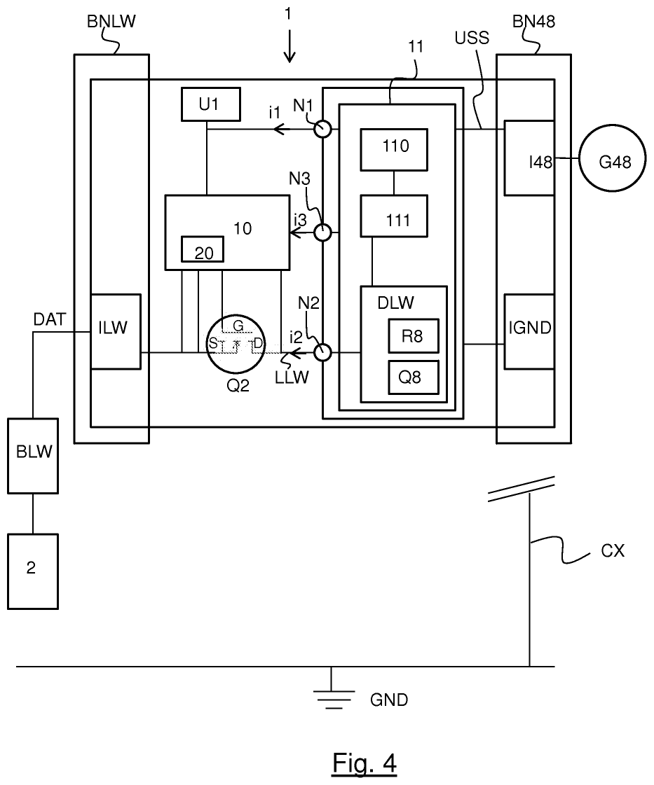

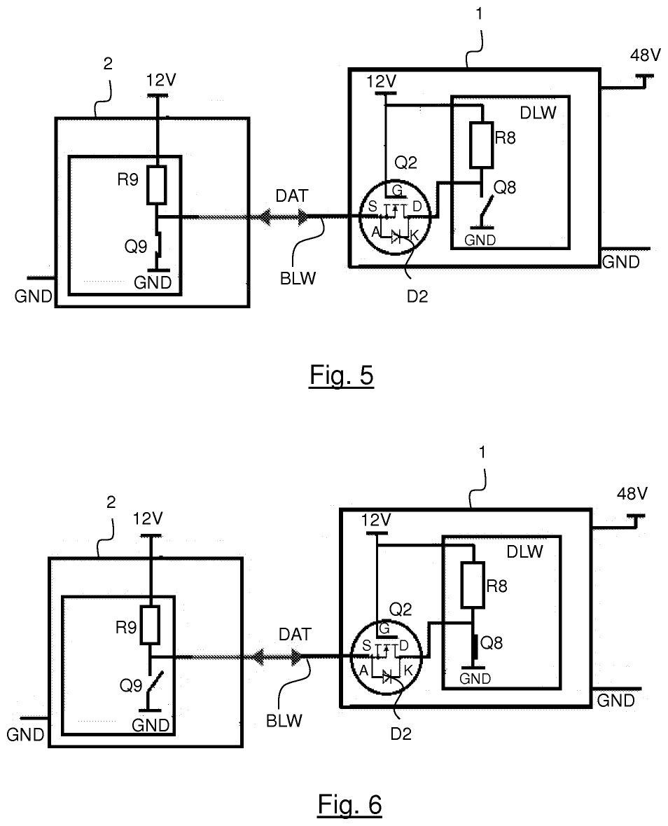

The electronic driver module DLW is described hereinbelow with reference to FIGS. 5 and 6 in its mode of operation when:
there is no short circuit CC and therefore when there is no overvoltage USS;
the common ground GND is not lost.

In the interests of simplification, the mode of operation is described with a bidirectional communication bus BLW.

The electronic driver module DLW is designed to be powered by the first voltage U1. It is thus linked to the voltage regulator of the functional module 11 and to the common ground GND via the functional module 11. It is linked to the voltage regulator via its pull-up resistor R8 and to the common ground GND via its switch Q8.

The electronic driver module DLW is designed to receive and/or transmit signals DAT via the communication bus BLW. It transmits the received signals DAT to the electronic driver element 111 of the functional module 11, said electronic driver element 111 interpreting these signals DAT so as to control the driving loads 110.

In a nonlimiting embodiment, said air pulser 1 is designed to operate in slave mode, and forms a slave module. As illustrated in FIGS. 5 and 6, the electronic driver module DLW is designed to receive and transmit signals DAT over the communication bus BLW from and to an external electronic device 2 called master module.

In a nonlimiting embodiment, the signals DAT are low logic signals. In a nonlimiting example, the low logic signals DAT are 0 V signals. It will be noted that in the case of the LIN protocol, the low logic signals are so-called dominant signals.

When the switch Q8 is open (FIG. 5), the pull-up resistor R8 brings the drain D of the main switch Q2 of the slave module 1 to 12 V. When the switch Q8 is closed (FIG. 6), the switch brings the drain D of the main switch Q2 of the slave module 1 to the common ground GND.

The external electronic device 2 operates in master mode and comprises a switch Q9 and a pull-up resistor R9. The master module 2 is powered by a low-power voltage.

The master module 2 is linked to a low-power electrical power supply network via its pull-up resistor R9 and to the common ground GND via its switch Q9.

When the switch Q9 is open (FIG. 6), the pull-up resistor R9 brings the communication bus BLW to 12 V which causes the source S of the main switch Q2 of the slave module 1 to be at 12 V. When the switch Q9 is closed (FIG. 5), the switch brings the communication bus BLW to the ground which causes the source S of the switch Q2 of the slave module 1 to be at 0 V.

It will be noted that by default (namely when the air pulser 1 is powered or not), the switches Q8 and Q9 are open. That therefore corresponds to their initial state. The LIN protocol and the master-slave operation prevents them from closing at the same time. It will be noted that, for the PWM protocol which is unidirectional, it is not possible to have such collisions.

A slave module 1 and the master module 2 forms a communication network NLW. In a nonlimiting embodiment, the communication network NLW can comprise a plurality of slave modules 1.

In a nonlimiting embodiment, the switches Q8 and Q9 are NPN switches.

In a nonlimiting embodiment, the master module 2 is the engine control unit ECU of the motor vehicle or even an electronic device linked to the dashboard of the motor vehicle.

In this case, the signals DAT are, in a nonlimiting example:
air flow rate setpoints sent from the master module 2 to the air pulser 1; and
diagnostic information sent to the from the master module 2 by the air pulser 1. In nonlimiting examples, this information indicates short circuits, overvoltages, undervoltages, overtemperatures, failing equipment, electrical consumption of the air pulser 1, etc.

As illustrated in FIGS. 5 and 6, the master module 2 is powered by a voltage of 12 V in the nonlimiting example taken illustrated in FIGS. 5 and 6.

FIG. 5 illustrates the sending of signals DAT from the master module 2 to the air pulser 1 and FIG. 6 illustrates the sending of signals DAT from the air pulser 1 to the master module 2.

When the master module 2 communicates with the slave module 1, it sends signals DAT to it. To this end, the switch Q9 switches so that 0 V signals (corresponding to a logic 0 signal) or 12 V signals (corresponding to a logic 1 signal) are sent over the communication bus BLW to the slave module 1. When the switch Q9 closes, a logic 0 signal is sent, when the switch Q9 opens, a logic 1 signal is sent. The switch Q8 for its part always remains open.

When the slave module 1 responds to the master module 2, the switch Q8 switches so that 0 V signals (corresponding to a logic 0 signal) or 12 V signals (corresponding to a logic 1 signal) are sent over the communication bus BLW to the master module 2. When the switch Q8 closes, a logic 0 signal is sent, when the switch Q9 opens, a logic 1 signal is sent. The switch Q9 for its part always remains open.

Thus, as illustrated in FIG. 5, when the master module 2 sends signals DAT to the air pulser 1, it imposes a zero on the communication bus BLW (in the case where the signals DAT are low logic), the latter then being at the ground potential GND. To this end, it closes its switch Q9. On the source S, there is therefore 0 V, and on the gate there is 12 V (since the main switch Q2 receives on its gate G 12 V from the connection interface 112). The voltage Vgs of the main switch Q2 is therefore equal to 12 V (and therefore higher than a threshold voltage Vgsth) which causes said main switch Q2 to be closed. The signals DAT therefore arrive correctly at the input of the electronic driver module DLW.

As illustrated in FIG. 6, when the slave module, here the air pulser 1, sends signals DAT to the master module 2, it imposes a zero (in the case where the signals DAT are low logic) on the drain D of the main switch Q2. To this end, the slave module 1 closes its switch Q8. The switch Q8 is closed, the drain D is at the ground potential GND, i.e. at 0 V.

It will be noted that the communication network NLW comprises a master module 2 and can comprise a plurality of slave modules 1, of which at least one slave module is powered by the first voltage U1 and by the second voltage U2. The other slave modules 1 can be powered in the same way or only by the first voltage U1.

It will be noted that the communication bus BLW makes it possible to route signals DAT from the master module 2 to all of the slave modules 1. Thus, if a short circuit CC occurs which generates an overvoltage USS on the air pulser 1 described above which is a slave module, it is disconnected from the communication network NLW by virtue of the first protection module 10, but the master module 2 and the other slave modules 1 continue to operate without being disturbed by the failing slave module (that which has undergone an overvoltage). The communication network NLW is thus protected from an overvoltage USS on one of its slave modules 1.

Thus, by protecting the communication bus BLW, the other slave modules 1 which have not undergone an overvoltage USS are also protected.

Thus, the first protection module 10 prevents:
the destruction of the other slave modules 1; or
the disruption of the communication between the other slave modules and the master module 2.

Freewheeling Diode D2

It will be noted that, as illustrated in FIGS. 5 and 6, in a nonlimiting embodiment, the main switch Q2 comprises a freewheeling diode D2 (also called “body diode”).

The freewheeling diode D2 is designed to guarantee the closing of the main switch Q2.

The freewheeling diode D2 is arranged between the drain D and the source S of the main switch Q2.

When the drain D is at 0 V, the freewheeling diode D2 switches to the on state.

It is recalled that a freewheeling diode is on when the voltage V_{AK} equal to the potential difference between V_{A} its anode A and Vₖ its cathode K is greater than or equal to a threshold voltage VS2 (given by the manufacturer).

In a nonlimiting example, VS2=0.6 V.

Thus, when the drain D is at 0 V, the voltage Vₖ is at 0 V. Moreover, V_{A} is at 12 V since, before the switch Q8 closes, the source of the main switch Q2 was at 12 V (by virtue of the pull-up resistor R9 seen previously). Thus, V_{AK} is equal to 12 V, i.e. higher than 0.6 V.

The freewheeling diode D2, when it is on, imposes 0.6 V on the source S of the main switch Q2, and causes the voltage Vgs to rise from 0 V (when Q2 is open, Vgs=0 V) to 11.4 V (12 V−0.6 V). This voltage Vgs value is sufficient for the main switch Q2 to close. When it closes, it links its drain voltage D to its source S so that Vds is substantially equal to 0 V (to within a stray resistance Rdson) and the voltage Vgs is substantially equal to 12 V. Thus, the signals DAT at 0 V arrive correctly at the input of the master module 2.

The freewheeling diode D2 thus makes it possible to correctly close the main switch Q2. Otherwise, the source S would remain at the potential of 12 V and, the gate being at 12 V, Vgs would be lower than Vgsth and said main switch Q2 would remain open. It is recalled that, in a nonlimiting example, Vgsth=2 V.

It will be noted that when the main switch Q2 is open (off state) (for example upon an overvoltage USS or upon a loss of common ground GND as described hereinbelow), it is not controlled and Vgs<Vgsth, or Vgs=0 V in a nonlimiting example and V_{AK}≠0 V (V_{AK} can rise to 48 V) and the freewheeling diode D2 returns to an off state. It will be noted that the freewheeling diode D2 is not destroyed by this high voltage since the breakdown voltage of the main switch Q2 is higher than 48 V.

It will be noted that if there is no overvoltage USS, and when the switches Q8 and Q9 are open (by default), the gate G and the source S of the main switch Q2 are at 12 V, and V_{gs}=0 V. The main switch Q2 is then open. Likewise, if the common ground GND is correctly connected and the switches Q8 and Q9 are open (by default), the gate G and the source S of the main switch Q2 are at 12 V, and V_{gs}=0 V. The main switch Q2 is then open.

Protection Diode D7

In a nonlimiting embodiment, the air pulser 1 further comprises a protection diode D7.

The protection diode D7 comprises a threshold voltage VS7. In a nonlimiting embodiment, the threshold voltage VS7 is equal to 22 V.

The protection diode D7 is designed to protect the communication bus BLW and the second connection interface ILW against a dangerous increase in the voltage U1, particularly if the voltage U1 on the node N1 is higher than or equal to its threshold voltage VS7.

In effect, there can be failures in the electrical power supply network G48 which can lead to failures in the voltage regulator. That causes the voltage U1 generated by said voltage regulator to rise greatly in terms of potential.

Likewise, there can be, directly, failures in the voltage regulator (DC/DC converter or linear regulator) which can also cause the voltage U1 generated by said voltage regulator to rise greatly in terms of potential. This rise in potential can damage the communication bus BLW if it is too great.

The protection diode D7 is connected between the emitter E of the first protection switch Q1 and the emitter E of the secondary switch Q6.

The protection diode D7 is designed to close the first protection switch Q1 when the voltage U1≥VS7.

In a nonlimiting embodiment, the protection diode D7 is a zener diode. If the voltage U1 is higher than or equal to its threshold voltage VS7, the zener diode D7 switches to the on state. A current i7 (illustrated in FIG. 2a) then passes through said zener diode D7. This current i7 powers the first protection switch Q1 which closes.

The closing of the first protection switch Q1 leads to the opening of the second protection switch Q4. This opening leads to the opening of the secondary switch Q6 and consequently the opening of the main switch Q2 as described later. The communication bus BLW is thus protected.

As seen above, when the regulation of the voltage U1 is no longer ensured, there is a rise in potential to 48 V and, on the node N1, there is a potential difference of 48 V−0 V (0 V corresponding to the signals DAT). At this moment U1≥VS7. This potential difference leads to the appearance of a current i1 which could circulate from the functional module 11 to the communication bus BLW (via the secondary switch Q6 and via the second connection interface ILW) and damage it. Now, if U1≥VS7, the protection diode D7 makes it possible to open the secondary switch Q6 as seen above. The secondary switch Q6 therefore prevents the current i1 from circulating to the communication bus BLW. The current i1 will return to the functional module 11.

First Protection Module 10

The first protection module 10 is illustrated in detail in FIG. 2a.

The first protection module 10 is designed to isolate the communication bus BLW from the electrical power supply network G48 when there is an overvoltage USS between the functional module 11 and the second connection interface ILW.

Such an overvoltage USS is located on the first node N1, on the second node N2 and on the third node N3.

It is recalled that an overvoltage USS exists when the voltage between the functional module 11 and the second connection interface ILW is higher than the voltage U1.

In a nonlimiting embodiment, the first protection module 10 comprises:
an overvoltage detection module 100 comprising:
   a protection diode D1
   a first protection switch Q1 designed to close when the protection diode D1 switches to the on state;
a secondary switch Q6 designed to open when there is such an overvoltage USS so as to open the main power switch Q2;
a second protection switch Q4 designed to open when the first protection switch Q1 closes so as to open the secondary switch Q6.

The various elements of the protection module 10 are described in detail hereinbelow.

Overvoltage Detection Module 100

The overvoltage detection module 100 is illustrated in detail in FIG. 2a.

[symbol] Protection Diode D1

The protection diode D1 is arranged between the main switch Q2 and the first protection switch Q1. Its cathode K is linked to the drain D of the main switch Q2 and its anode A is linked to the base B of the first protection switch Q1 and to the common ground GND via a resistor R1 described later.

In a nonlimiting embodiment, the protection diode D1 comprises a threshold voltage VS1 higher than the voltage U1, namely higher than 12 volts.

In a nonlimiting example, the threshold voltage VS1=22 V.

The protection diode D1 is in the on state when V_{AK}≥−VS1.

When there is a short circuit CC which generates an overvoltage USS, the voltage U10 (illustrated in FIGS. 2a, 2b and 3) on the second node N2 and therefore on the communication line LLW is equal to the overvoltage USS generated by the short circuit CC and is therefore higher than the voltage U1 (equal to 12 V in the nonlimiting example taken). Therefore, Vk=U10 and V_{A}=0 V (because the anode is connected to the common ground GND via the resistor R1). Therefore V_{KA}=U10 and therefore V_{KA}≥22 V. Thus there is a current i_{KA} which circulates from the cathode K to the anode A of the protection diode D1. The protection diode D1 thus switches to the on state.

In a nonlimiting embodiment, the protection diode D1 is a zener diode. Thus, if the voltage U10 becomes higher than or equal to this voltage VS1, the zener diode D1 clips said voltage U10 so that it is equal to the threshold voltage VS1.

When the protection diode D1 is in the on state, that leads to the closure of the first protection switch Q1 because the latter is, in this case, powered by the voltage U10. In this case, in effect the voltage on the base B V_{B}=U10 (clipped), the voltage on the emitter E V_{E}=0 V because the emitter E is linked to the common ground GND, and therefore V_{BE}=U10 (clipped), which is higher than the conduction threshold voltage of the protection diode D1. The protection diode D1 has thus made it possible to detect an overvoltage USS.

It will be noted that the time to detect an overvoltage USS is of the order of a microsecond.

[symbol] First Protection Switch Q1

The first protection switch Q1 is connected to the second protection switch Q4.

In a nonlimiting embodiment, the first protection switch Q1 is a bipolar transistor. In a nonlimiting variant embodiment, the bipolar transistor Q1 is of NPN type. Its collector C is linked to the base B of the second protection switch Q4. The node N7 illustrated in FIG. 2a forms the connection between the base B of the second protection switch Q4, the collector C of the first protection switch Q1 and a resistor R3 illustrated in FIG. 2a. Moreover, its emitter E is linked to the common ground GND, and its base B is linked to the protection diode D1 and to the resistor R1 (described later).

The resistor R3 makes it possible to apply to the collector C of the first protection switch Q1 the first voltage U1, namely 12 V.

By default, the first protection switch Q1 is open. When the first protection switch Q1 is open, the base B of the second protection switch Q4 is linked to 12 V via a resistor R3. The resistor R3 in effect brings the 12 V potential to the base B of the second protection switch Q4. The resistor R3 makes it possible to control the second protection switch Q4 and thus makes it possible to keep the second protection switch Q4 closed.

When the first protection switch Q1 closes, its emitter E is reconnected to the common ground GND and the node N7 is consequently linked to the common ground GND. The base B of the second protection switch Q4 is then linked to the common ground GND. The consequence of that is that there is no longer any current circulating 1b4 in the second protection switch Q4. The latter therefore opens. It is no longer controlled by the resistor R3.

It will be noted that the first protection switch Q1 comprises an internal resistor between its base B and its emitter E and an internal base resistor B. These internal resistors make it possible to close the first protection switch Q1 when the protection diode D1 switches to the on state. It will be noted that the use of the internal pulling resistors allows for a space-saving.

It will be recalled that the first protection switch Q1 closes when there is a short circuit CC and therefore an overvoltage USS as seen previously.

[symbol] Resistor R1

In a nonlimiting embodiment, the first protection module 10 further comprises a resistor R1.

The resistor R1 is linked to the common ground GND and to the protection diode D1 seen previously.

The resistor R1 is designed to make the protection diode D1 operate so as to control the first protection switch Q1 through its internal resistors. The resistor R1 allows a current to pass through the protection diode D1. In effect, as seen previously, when there is a short circuit CC, there is a potential difference at the terminals of the protection diode D1, with V_{K}=U10 clipped and V_{A}=0 V. By virtue of the resistor R1, there is therefore a current i_{KA} which circulates from the cathode K to the anode A of the protection diode D1. The protection diode D1 thus rightly switches to the on state.

It will be noted that the voltage at the terminals of the resistor R1 is the clipped voltage U1 seen previously. In a nonlimiting example, the current (not illustrated) passing through the resistor R1 and therefore through the protection diode D1 is of the order of a milliampere.

Second Protection Switch Q4 The second protection switch Q4 is designed to open:
upon an overvoltage USS; or
upon the loss of the common ground GND
   so as to open the secondary switch Q6.

The second protection switch Q4 is linked to the voltage regulator which supplies the first voltage U1 via a resistor R3. It will be noted that the second protection switch Q4 is not directly linked to the voltage regulator.

The resistor R3 is designed to control the second protection switch Q4. The resistor R3 is designed to limit a current which could circulate between the voltage regulator and the base B of the second protection switch Q4 in the case where the first protection switch Q1 would close. In effect, in this case, without the resistor R3, between the voltage regulator and the common ground GND, there would be a short circuit which would generate a current in the second protection switch Q4 of a few thousand amperes. Said second protection switch Q4 could not withstand so high a current. The resistor R3 thus makes it possible to protect said second protection switch Q4 by limiting the current circulating in its base B, referenced 1b4. The resistor R3 is thus rated to have a base B current 1b4 matched to the second protection switch Q4. Likewise, the resistor R3 is designed to limit a current which could circulate between the voltage regulator and the base B of the first protection switch Q1. The resistor R3 is a so-called “pull-up” resistor.

The second protection switch Q4 is arranged between the first protection switch Q1 and the secondary switch Q6.

In a nonlimiting embodiment, the second protection switch Q4 is a bipolar transistor. In a nonlimiting variant embodiment, the bipolar transistor Q4 is of NPN type. Its collector C is linked to the base resistor R14 (described later), its emitter E is linked to the common ground GND (via the secondary blocking diode D11 described later), its base B is linked to the collector C of the first protection switch Q1.

The third node N3 links in particular the functional module 11 and the second protection switch Q4.

The second protection switch Q4 is by default closed. When it is closed, the second protection switch Q4 is controlled by the resistor R3. The second protection switch Q4 further comprises an internal pulling resistor (illustrated but not referenced) situated between its base B and its emitter E and an internal pulling resistor situated between the resistor R3 and its base B. These internal pulling resistors with the resistor R3 make it possible to apply to the emitter E of the second protection switch Q4 the first voltage U1, namely 12 V.

The use of the internal pulling resistors allows for a space-saving.

The second protection switch Q4 is closed when the first protection switch Q1 is open as seen previously.

The second protection switch Q4 opens when the first protection switch Q1 closes as seen previously.

When there is a short circuit CC, as seen previously, an overvoltage USS is detected by the overvoltage detection module 100 (in particular the protection diode D1 or the protection diode D7), which leads to the closure of the first switch Q1. At this moment, the second protection switch Q4 opens because there is no longer any current 1b4 circulating in the second protection switch Q4 as seen previously.

The opening of the second protection switch Q4 causes the base resistor R14 (described later) to be disconnected from the common ground GND. The base B of the secondary switch Q6 is no longer connected to the common ground GND, it becomes floating. The 12 V potential is therefore set up. In effect, by virtue of the secondary pulling resistor R15 (described later), the base B of the secondary switch Q6 rises to 12 V. A potential difference is then obtained between the emitter E and the base B which is zero V_{BE}=0 (the emitter E of the secondary switch Q6 being at the potential of 12 V), which causes the secondary switch Q6 to open.

Thus, when the second protection switch Q4 opens, it leads to the opening of the secondary switch Q6, and consequently the opening of Q2 (as described later) so that the communication bus BLW is disconnected from the electrical power supply network G48. It is no longer disturbed by a short circuit CC and therefore by an overvoltage USS.

Upon the loss of common ground GND, the emitter E of the second protection switch Q4 is floating. In this case, no current can pass in the emitter E. The current ie4 (not illustrated) in the emitter E is therefore zero. Since ie4=ib4+ic4 and ib4 and ic4 (not illustrated) cannot be negative, therefore ib4=0, the second protection switch Q4 therefore opens. The opening of the second protection switch Q4 leads to the opening of the secondary switch Q6, the latter leading to the opening of the main switch Q2 as described hereinbelow.

Secondary Switch Q6

The secondary switch Q6 is designed to open:
upon an overvoltage USS; or
upon the loss of the common ground GND so as to open the main switch Q2.

The secondary switch Q6 is by default closed.

In a nonlimiting embodiment, the secondary switch Q6 is a bipolar transistor. In a nonlimiting variant embodiment, the bipolar transistor Q6 is of PNP type. Its base B is linked to the collector C of the second protection switch Q4, its emitter E is connected to the voltage regulator (here DC/DC), and its collector C is connected to the gate G of the main switch Q2.

When a short circuit CC occurs which generates an overvoltage USS, the base B of the secondary switch Q6 is open circuit, the second protection switch Q4 having been opened. The base B is floating (as described previously) because it is no longer connected to the common ground GND. The base current Ib6 (current which circulates in the base B of the secondary switch Q6) is therefore equal to 0, which causes said secondary switch Q6 to open. It is said to be in a blocked state.

When a short circuit CC occurs which generates an overvoltage USS, the second node N2 rises to the 48 V potential and a potential difference, here of 48 V−0 V (signals DAT are transmitted), thus appears on the second node N2 and on the electronic driver module DLW, which generates the current i2 which circulates on the communication bus BLW via the main switch Q2 if the latter is closed and if signals DAT circulate on the communication bus BLW, said signals DAT being at 0 V as described previously. The electronic driver module DLW and the communication bus BLW do not support such a current i2 and therefore risk being damaged. The secondary switch Q6 (which is opened as seen previously following the detection of the overvoltage USS by the protection diode D1) makes it possible to open the main switch Q2 and thus prevents such a current i2 from circulating in the communication bus BLW (via the second connection interface ILW). The latter is thus protected as is the second connection interface ILW.

In effect, when the secondary switch Q6 opens, the main switch Q2, in particular its gate G (connected to the collector C of the secondary switch Q6) in the nonlimiting example of the MOSFET, is no longer powered by the voltage U1, namely 12 V, and therefore the potential of the gate G is equal to 0 V. In effect, the tertiary blocking diode D6 prevents the main pulling resistor R7 from allowing a voltage to pass from the source S to the gate G.

Since the source S of the main switch Q2 is either at the potential of 12 V or at the potential of 0 V depending on the switching of the switches Q8, Q9 described previously, V_{GS}=−12 V or V_{GS}=0 V, which does not allow the closure of the main switch Q2 because V_{GS} is lower than the threshold voltage Vgsth of the main switch Q2 which is 2 V in a nonlimiting example. The main switch Q2 therefore opens.

Thus there is no longer current i2 which circulates on the communication bus BLW. The second connection interface ILW, and the communication bus BLW are thus protected. By opening the main switch Q2 upon a short circuit CC and therefore upon an overvoltage USS, the network G48 has thus been disconnected from the communication bus BLW.

Upon a loss of common ground GND, the second protection switch Q4 opens as seen previously, which leads to the opening of the secondary switch Q6, which is in a blocked state. When the secondary switch Q6 opens, that makes it possible to open the main switch Q2. By opening the main switch Q2 upon the loss of common ground GND, the network G48 has thus been disconnected from the communication bus BLW.

Main Pulling Resistor R7

In a nonlimiting embodiment, the air pulser 1 further comprises a main pulling resistor R7.

The pulling resistor R7 is designed to guarantee the opening of the main switch Q2 when said main switch Q2 has to open (upon an overvoltage USS or upon a loss of common ground GND).

The main pulling resistor R7 is linked to the cathode K of the tertiary blocking diode D6 and to the source S of the main switch Q2. It is recalled that a pulling resistor makes it possible to initialize the state of the gate G of a switch.

By default, the control level applied (namely the value of the voltage applied) to the gate G of the main switch Q2 is indeterminate (the gate sees neither the 12 V voltage nor the 0 V voltage). It is in a floating state and could force the latter to start conducting, either totally (with risk of erratic operation of the air pulser 1), or partially (with risk of destruction of the main switch Q2).

When the air pulser 1 is powered, and there is no fault such as a short circuit CC or a loss of common ground GND, the potential of the gate G of the main switch Q2 is 12 V because the secondary switch Q6 is closed.

When the secondary switch Q6 is closed, the node N4 (and the node N5) illustrated in FIG. 2a is at the potential of the voltage U1, namely 12 V in the example.

When the secondary switch Q6 opens (because of an overvoltage USS or a loss of common ground GND), the main switch Q2 opens. The node N4 corresponds to the gate voltage V_{G} of the main switch Q2. The node N4 (and the node N5) becomes floating. There is therefore a potential difference between the source S (which is at 0 V because of the signals DAT) of the main switch Q2 and the node N4, i.e. the gate G of the main switch Q2. This potential difference generates a current (not illustrated) which will circulate in the tertiary blocking diode D6 and the main pulling resistor R7 and will go to the source S and the resettable fuse R6. The node N4 (and the node N5) will thus drop to the 0 V potential of the source S. The pulling resistor R7 allows the node N4 and therefore the gate G of the main switch Q2 to be at 0 V rapidly. Thus, the voltage Vgs will be at 0 V which guarantees the opening of the main switch Q2.

The main pulling resistor R7 is a so-called “pull-up” resistor.

Secondary Pulling Resistor R15

In a nonlimiting embodiment, the air pulser 1 further comprises a secondary pulling resistor R15.

The secondary pulling resistor R15 is designed to guarantee the opening of the secondary switch Q6 when said secondary switch Q6 has to open (upon an overvoltage USS or upon a loss of common ground GND).

The secondary pulling resistor R15 is linked to the base B and to the emitter E of the bipolar transistor Q6.

The secondary pulling resistor R15 makes it possible to control the secondary switch Q6 to open when its base B is floating, namely when the second protection switch Q4 opens as described previously. In effect, this secondary pulling resistor R15 makes it possible to initialize the voltage V_{BE} of the secondary switch Q6 to 0 V (which is therefore by default at 0 V) which guarantees the opening of the secondary switch Q6 when there is no current Ib6 circulating in the base B of said secondary switch Q6.

The secondary pulling resistor R15 is a so-called “pull-up” resistor.

Secondary Blocking Diode D11

In a nonlimiting embodiment, the air pulser 1 further comprises a secondary blocking diode D11.

The secondary blocking diode D11 is designed to prevent a current i3 from circulating in the second protection switch Q4. It thus ensures the protection of the second protection switch Q4 upon a short circuit CC.

The secondary blocking diode D11 is arranged between the functional module 11 and the second protection switch Q4. The third node N3 thus links in particular the functional module 11 and the secondary blocking diode D11. The secondary blocking diode D11 is linked to the common ground GND via the functional module 11. In particular, the anode A of the secondary blocking diode D11 is linked to the emitter E of the second protection switch Q4, and its cathode K is linked to the common ground GND.

When there is a short circuit CC which generates an overvoltage USS, from the point of view of the emitter E of the second protection switch Q4, the node N3 rises to the potential of 48 V (all the functional module 11 having risen to the potential of 48 V), namely the emitter E is back at 48 V. Consequently, there is therefore a potential difference of 48 V−12 V between the emitter E of the second protection switch Q4 and its base B, the latter being at 12 V (when the first protection switch Q1 is open). That therefore generates a current i3 which is back on the emitter E of the second protection switch Q4 and is too great for the second protection switch Q4. The second protection switch Q4 then risks breaking. Consequently, the protection of the main switch Q2 is no longer assured.

The same applies when the common ground GND is lost.

The secondary blocking diode D11 is designed to prevent such a current i3 from circulating in the second protection switch Q4. It thus protects said second protection switch Q4.

The secondary blocking diode D11 prevents the courant i3 from passing when it is in a blocked state. To this end, the secondary blocking diode D11 is in a blocked state when its voltage V_{AK} equal to the potential difference V_{A} at its anode A and V_{K} at its cathode K is lower than its threshold voltage VS11 (given by the manufacturer). In a nonlimiting example, VS11=0.6 V. There is such a difference when there is an overvoltage USS. In effect, in this case, V_{A}=12 V (the 12 V voltage being applied to the emitter E of the second protection switch Q4 via the resistor R3 and its internal pulling resistor situated between its base B and its emitter E, emitter E linked to the anode A of the secondary blocking diode D11) and V_{K}=48 V (the third node N3 having risen to the potential of 48 V). Therefore V_{AK} negative<VS11. When the secondary blocking diode D11 is blocked, there is no potential difference at the terminals of the second protection switch Q4. In effect, V_{E}=12 V (the 12 V voltage being applied via the resistor R3 and its internal pulling resistor situated between its base B and its emitter E) and V_{B}=12 V (Q1 open, the node N7 is at 12 V). V_{EB}=0 V is obtained. It will be noted that the same applies when the common ground GND is lost.

It will be noted that the secondary blocking diode D11 is in the on state when V_{AK}>Vs. This is obtained when there is no short circuit CC. In effect, in this case, V_{A} is at the 12 V potential and Vₖ is at the ground potential. It will be noted that the same applies when the common ground GND is not lost.

Base Resistor R14

In a nonlimiting embodiment, the air pulser 1 further comprises a base resistor R14.

The base resistor R14 is designed to set the base current Ib6 which circulates in the secondary switch Q6.

The base resistor R14 is arranged between the secondary switch Q6 and the second protection switch Q4. In particular, the base resistor R14 is linked to the base B of the secondary switch Q6 and to the collector C of the second protection switch Q4.

The base resistor R14 makes it possible to control the secondary switch Q6 to close by virtue of the base current Ib6 that it supplies. In effect, the setting of the base current Ib6 makes it possible to guarantee the closure of the secondary switch Q6. Furthermore, that avoids having an excessively high current Ib6 which would risk breaking the component Q6.

It is recalled that the threshold value of Ib6 for the secondary switch Q6 to close is Ib6>Ic/β with Ic the collector current and β the current amplification of the secondary switch Q6 given by the manufacturer of the secondary switch Q6.

Second Protection Module 20

The second protection module 20 is illustrated in detail in FIG. 2b.

The second protection module 20 is designed to isolate the communication bus BLW from the electrical power supply network G48 upon a loss of the common ground GND.

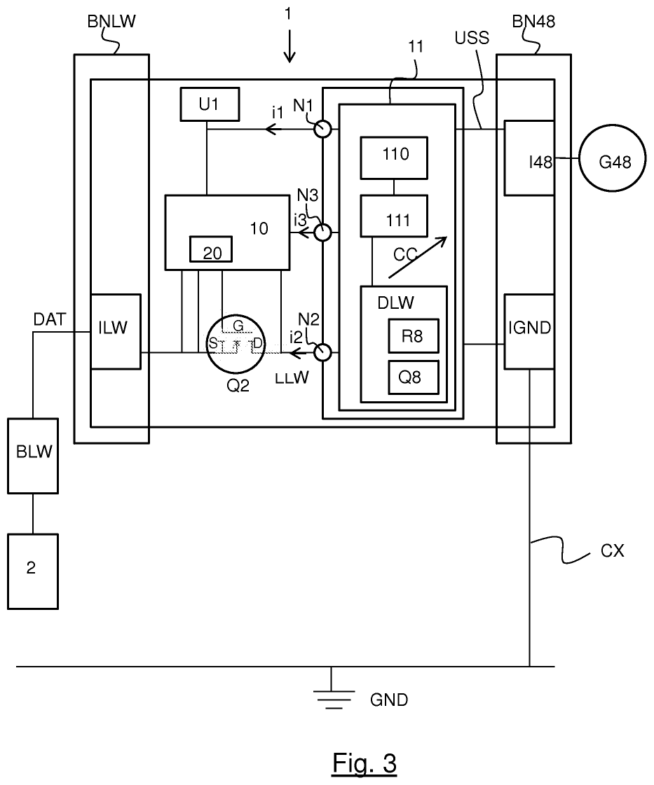

The common ground GND is lost when the ground connection cable CX which links the first connection interface I48 to the common ground GND is cut as illustrated in FIG. 4.

The second protection module 20 forms part of the first protection module 10. In effect, it comprises:
the secondary switch Q6 described previously;
the second protection switch Q4 described previously;
the secondary blocking diode D11 described previously;
the secondary pulling resistor R15 described previously;
the base resistor R14 described previously.

In a nonlimiting embodiment, the second protection module 20 further comprises the main pulling resistor R7.

When the common ground GND is lost, all of the components of the functional module 11 rise to the potential of the voltage U2 supplied by the electrical power supply network G48. That leads to the appearance of potential differences and consequently of currents which circulate between said functional module 11 and:
the second protection module 20;
the communication bus BLW.

These currents risk damaging in particular the communication bus BLW. The second protection module 20 makes it possible to protect these elements against said currents as follows.

When the common ground GND is lost, the functional module 11 rises to the potential of 48 V. The electrical nodes N1, N2 and N3 become floating, because they are no longer referenced to the common ground. They then rise to the potential of 48 V.

At the first node N1, a potential difference of 48 V−12 V appears (between the first node N1 and the second connection interface ILW) which leads to the appearance of the current i1 (illustrated in FIG. 4) circulating from the functional module 11 to the communication bus BLW (via the second connection interface ILW) which risks damaging it as well as the second connection interface ILW. The second protection switch Q4 opens, cascade-wise, the secondary switch Q6 and the main switch Q2 (as described previously), which allows the secondary switch Q6 to prevent such a current i1 from circulating.

At the second node N2, on the side of the drain D of the main switch Q2, a potential difference of 48 V−0 V (between the second node N2 and the communication bus BLW) appears which leads to the appearance of a current i2 (illustrated in FIG. 4) circulating from the electronic driver module DLW to the communication bus BLW (via the second connection interface ILW) which risks damaging them. The second protection switch Q4 opens, cascade-wise, the secondary switch Q6 and the main switch Q2 (as described previously) which allows the main switch Q2 to prevent such a current i2 from circulating in the communication bus BLW. The latter is thus protected as is the second connection interface ILW.

Moreover, when the common ground GND is lost, the electronic driver module DLW is no longer referenced to the ground. It rises to the potential of 48 V (all the functional module 11 having risen to the potential of 48 V). Without the second protection module 20, the electronic driver module DLW would see at its terminals a potential difference of 48 V−0 V which corresponds to the difference between the potential of 48 V (applied to the functional module 11) and the potential of 0 V of the signals DAT transmitted over the communication bus BLW. This potential difference leads to the appearance of a current i2 (illustrated in FIG. 4) which circulates in said electronic driver module DLW which would risk damaging it. In effect, the electronic driver module DLW does not support such a high potential difference. In a nonlimiting example, it supports a potential difference lower than or equal to 24 V. The second protection switch Q4 opens, cascade-wise, the secondary switch Q6 and the main switch Q2 (as described previously) which allows the main switch Q2 to prevent the current i2 from circulating when the common ground GND is lost, so there will no longer be a potential difference at the terminals of the electronic driver module DLW and therefore no longer a current i2 circulating. The electronic driver module DLW will only be at the potential of 48 V. It will thus not be damaged.

Thus, contrary to a short circuit CC which occurs in the functional module 11 where the electronic driver module DLW will definitely be defective, even destroyed, said electronic driver module DLW will be protected in case of loss of common ground GND. Thus, the electronic driver module DLW is not protected by the first protection module 10 against a short circuit CC, but it is protected by the second protection module 20.

At the third node N3, a potential difference of 48 V−0 V between this third node N3 and the communication bus BLW (all the functional module 11 having risen to the potential of 48 V) which leads to the creation of a current i3 (illustrated in FIG. 4) between said third node N3 and said communication bus BLW. In effect, in this case, the third node N3 rises to the potential of 48 V while the communication bus BLW is at the potential of 0 V because of the signals DAT at 0 V. Upon a loss of common ground GND, the second protection switch Q4 opens as seen previously. It thus prevents such a current i3 from circulating and thus protects the communication bus BLW and the second connection interface ILW.

It will be noted that, with the first protection module 10, a detection of overvoltage USS is transformed into a detection of the loss of the common ground GND. Common components are used to protect the second connection interface ILW (and therefore the communication bus BLW) against the loss of the common ground GND and against said overvoltage USS. In effect, on detection of an overvoltage USS, the second protection switch Q4 opens which causes the base resistor R14 to be disconnected from the common ground GND as seen previously, which corresponds to a loss of the common ground GND. After the detection of an overvoltage USS, the rest of the operation of the protection against an overvoltage USS or against a loss of ground GND is the same for the first protection module 10 and for the second protection module 20 as seen previously.

Obviously, the description of the invention is not limited to the embodiments described above.

Thus, in another nonlimiting embodiment, the secondary switch Q6 can be a MOSFET transistor or an IGBT transistor. In these cases, the base resistor R14 is not necessary.

Thus, bidirectional or unidirectional protocols other than the LIN or PWM protocol can be used.

Thus, the invention can be applied also to an electric heating device 1 for a motor vehicle. Thus, according to a nonlimiting embodiment, the electric heating device 1 for a motor vehicle comprises:
a first connection interface I48 with an electrical power supply network G48 designed to supply the second voltage U2;
a second connection interface ILW with a communication bus BLW,
a functional module 11 linked to the first connection interface I48;
a main switch Q2 linked to the functional module 11 designed to convey signals DAT over the communication bus BLW,
a first protection module 10 designed to isolate the communication bus BLW from the electrical power supply network G48 when there is an overvoltage USS between the functional module 11 and the second connection interface ILW.
In this case, the functional module 11 comprises at least one resistive heating element 110 powered by the first voltage U1 and at least one associated electronic driving element 111 powered by the second voltage U2 and designed to control said resistive heating element 110. In a nonlimiting example, the resistive heating element 110 is a heating resistor. In another nonlimiting example, the resistive heating element 110 is a resistive track. In these two nonlimiting examples, the heat produced by the resistive heating element 110 is transmitted via a fluid circulation duct (not illustrated) to a fluid which can thus be heated.

Since such electric heating devices are known to the person skilled in the art, they are not described in detail here.

Thus, the invention described offers in particular the following advantages:
it is a solution that is simple to implement and inexpensive;
it makes it possible, by virtue of the first protection module 10 and of the main switch Q2, upon an overvoltage USS (in particular in case of short circuit CC) in the electrical power supply network G48 and therefore upon an overvoltage USS, to isolate the communication bus BLW from the first connection interface I48, and therefore from the electrical power supply network G48. It will thus not be damaged;
it makes it possible, by virtue of the second protection module 20 and of the main switch Q2, upon a loss of common ground GND, to isolate the communication bus BLW from the first connection interface I48, and therefore from the electrical power supply network G48. It will thus not be damaged;
it makes it possible, by virtue of the second protection module 20 and of the main switch Q2, to protect the electronic driver module DLW upon a loss of common ground GND.

1. An air pulser for a motor vehicle powered by a first voltage and by a second voltage, the air pulser comprising:
a first connection interface with an electrical power supply network that supplies the second voltage;
a second connection interface with a communication bus;
a functional module linked to the first connection interface;
a main switch linked to the functional module that conveys signals over the communication bus; and
a first protection module that isolates the communication bus from the electrical power supply network when there is an overvoltage between the functional module and the second connection interface.

2. The air pulser as claimed in claim 1, wherein the first protection module comprises:
an overvoltage detection module comprising:
a protection diode;
a first protection switch that closes when the protection diode is switched on;
a secondary switch that opens when there is said overvoltage so as to open the main switch;
a second protection switch that opens when the first protection switch closes so as to open the secondary switch.

3. The air pulser as claimed in claim 1, further comprising a protection diode that protects the communication bus when the first voltage is above a threshold voltage of said protection diode.

4. The air pulser as claimed in claim 2, wherein the air pulser further comprises a secondary blocking diode that prevents a current from circulating in the second protection switch.

5. The air pulser as claimed in claim 1, wherein the air pulser further comprises a main pulling resistor which guarantees the opening of the main switch when there is said overvoltage.

6. The air pulser as claimed in claim 2, further comprising a secondary pulling resistor that guarantees the opening of the secondary switch when there is said overvoltage.

7. The air pulser as claimed in claim 2, further comprising a base resistor which guarantees the closure of the secondary switch when a current circulates in said secondary switch.

8. The air pulser as claimed in claim 1, further comprising a resettable fuse that protects the communication bus against an overcurrent.

9. The air pulser as claimed in claim 1, further comprising a tertiary blocking diode that guarantees that the main switch remains open.

10. The air pulser as claimed in claim 1, further comprising a protection diode to protect the main switch against an increase in said first voltage.

11. The air pulser as claimed in claim 1, wherein the first voltage is generated from the second voltage.

12. The air pulser as claimed in claim 1, wherein the functional module comprises an electronic driver module powered by said first voltage and to receive and/or transmit signals via the communication bus.

13. An air pulser for a motor vehicle powered by a first voltage and by a second voltage, the air pulser comprising:
a first connection interface with an electrical power supply network that supplies the second voltage;
a second connection interface with a communication bus;
a functional module linked to the first connection interface;
a main switch linked to the functional module that conveys signals over the communication bus;
a first protection module that isolates the communication bus from the electrical power supply network when there is an overvoltage between the functional module and the second connection interface; and
a zener diode comprising a threshold voltage, wherein when a voltage of the main switch becomes greater than or equal to the threshold voltage, the zener diode clips said voltage of the main switch so that the voltage equals the threshold voltage.

14. An air pulser for a motor vehicle powered by a first voltage and by a second voltage, the air pulser comprising:
a first connection interface with an electrical power supply network that supplies the second voltage;
a second connection interface with a communication bus;
a functional module linked to the first connection interface;
a main switch linked to the functional module that conveys signals over the communication bus;
a first protection module that isolates the communication bus from the electrical power supply network when there is an overvoltage between the functional module and the second connection interface; and
a protection diode of the main switch arranged in parallel with a main pulling resistor and a tertiary blocking diode, the protection diode being configured to protect the main switch from a voltage increase of the first voltage between a gate and a source of the main switch.
